(19) United States
(12) Patent Application Publication
(10) Pub. No.: US 2005/0093112 A1
(43) Pub. Date: May 5, 2005

(54) Semiconductor package capable of absorbing electromagnetic wave

(76) Inventor: Sun-Ki Kim, Kyeonggi-do (KR)

Correspondence Address: ST. ONGE STEWARD JOHNSTON & REENS, LLC, 986 BEDFORD STREET, STAMFORD, CT, 06905-5619, US

(21) Appl. No.: 10/980,216

(22) Filed: Nov. 3, 2004

(30) Foreign Application Priority Data
Nov. 4, 2003 (KR) 2003/34550

(51) Int. Cl. H01L 23/495

(52) U.S. Cl. 257/666

(57) ABSTRACT

A semiconductor package has a semiconductor chip electrically connected to a conductive lead of a lead frame through a bonding wire and it is encapsulated by an insulating molding body. In such a semiconductor package, an electromagnetic wave absorbing film is formed by coating an electromagnetic wave absorbent on predetermined portions or either of the bonding wire and the conductive lead to a predetermined constant thickness, and the electromagnetic wave absorbing film forms a closed loop. In this manner, the electromagnetic interference between the conductive lead and the bonding wire can be surely attenuated. The lead frame and the conductive lead can be shield from the electromagnetic wave applied from the outside of the semiconductor package. In addition, the spurious signal flowing through the conductive lead and the bonding wire can also be reduced.

This application claims priority from pending Korean Patent Application No. 2003-34550 filed on Nov. 4, 2003.

### FIELD OF INVENTION

The present invention relates to a semiconductor package capable of absorbing an electromagnetic wave, and more particularly, to a semiconductor package capable of minimizing an electromagnetic interference generated in adjacent leads of a lead frame or in bonding wires, shielding a lead frame and a conductive lead from an electromagnetic wave propagated from an outside of the semiconductor package, and attenuating a spurious signal transferred through conductive leads of a lead frame and bonding wires.

### DESCRIPTION OF THE RELATED ART

In general, a semiconductor package can safely protect a semiconductor chip from an external environment and mount the semiconductor chip on a necessary position.

FIG. 1 is a perspective view, partially broken away, of a conventional DIP semiconductor package.

Referring to FIG. 1, a semiconductor package includes a semiconductor chip 1 mounted on a die pad 7, a conductive lead 2 disposed around the die pad 7, a bonding wire 8 for electrically connecting the semiconductor chip 1 and the conductive lead 2, and a molding body 9 for surrounding the entire elements including the semiconductor chip 1.

The semiconductor chip 1 is made of a semiconductor material, such as silicon. The semiconductor chip 1 is configured with a plurality of elements, such as resistors or transistors. Also, the conductive lead 2 is a portion of a lead frame. The conductive lead 2 electrically connects the semiconductor chip to a circuit board, such as a printed circuit board (PCT), and mechanically supports the semiconductor chip.

The bonding wire 8 electrically connects the conductive lead of the lead frame and the semiconductor chip. The molding body 9 encapsulates the semiconductor chip, the lead frame and the bonding wire so as to protect them from an external environment. The molding body 9 is generally formed of an epoxy-based polymer. The molding body 9 may also be formed of a ceramic so as to disperse heat as fast as possible.

Korean Utility Model Laid-Open Publication No. 1997-46884 discloses a semiconductor package in which an electromagnetic wave generated from a semiconductor chip is prevented from leaking to an outside of the semiconductor package.

According to the disclosure, electromagnetic-wave leakage protection members are tightly attached to a conductive lead on upper and lower portions of a semiconductor chip by a tape and are then molded.

However, while the conventional electromagnetic-wave leakage protection members can shield a portion of the electromagnetic wave radiated outwards from the semiconductor chip, it cannot protect the semiconductor chip from an electromagnetic interference (EMI) generated between the bonding wire and the conductive lead.

Although the above problem can be solved by widening the gaps between the conductive leads, there occurs another problem in the integration of the semiconductor chip.

### SUMMARY OF THE INVENTION

An object of the present invention is to provide a semiconductor package capable of minimizing an electromagnetic interference generated between a bonding wire and a conductive lead.

Another object of the present invention is to provide a semiconductor package capable of attenuating a spurious signal transferred through a bonding wire and a conductive lead.

According to one aspect of the present invention, there is provided a semiconductor package electrically connecting a semiconductor chip to a conductive lead of a lead frame through a bonding wire, the semiconductor package being encapsulated by an insulating molding body, wherein an electromagnetic wave absorbing film is formed by coating an electromagnetic wave absorbent on predetermined portions or either of the bonding wire and the conductive lead to a predetermined constant thickness, the electromagnetic wave absorbing film forming a closed loop.

The electromagnetic wave absorbing film may not be coated on both end portions of the bonding wire and the conductive lead.

The electromagnetic wave absorbent may be made by evenly mixing an electromagnetic wave absorbent powder with a liquid polymer resin.

The electromagnetic wave absorbent powder may be any one selected from the group consisting of carbon graphite, Ni—Zn based ferrite, Mn—Zn based ferrite, Cu—Zn based ferrite, Mg—Zn based ferrite and barium based ferrite. Size of the particle is below 50 μm and the ferrites are plasticized.

### BRIEF DESCRIPTION OF THE DRAWINGS

The above objects and other advantages of the present invention will become more apparent by describing in detail preferred embodiments thereof with reference to the attached drawings in which:

FIG. 1 is a perspective view, partially broken away, of a conventional DIP semiconductor package;

FIG. 2 is a perspective illustrating a structure for absorbing an electromagnetic wave according to the present invention; and

FIG. 3 is a perspective view illustrating a detailed structure for absorbing an electromagnetic wave in a bonding wire and a conductive lead connected thereto.

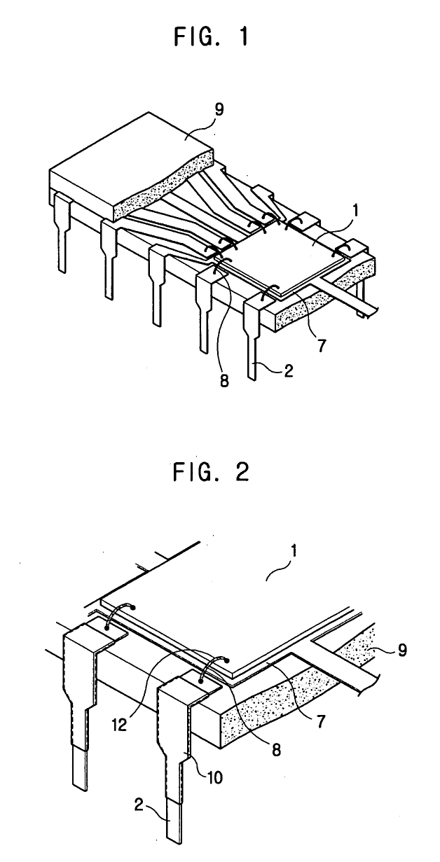

### DETAILED DESCRIPTION OF PREFERRED EMBODIMENTS

Now, preferred embodiments of the present invention will be described in detail with reference to the accompanying drawings.

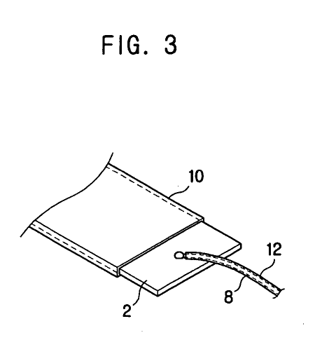

FIG. 2 is a perspective illustrating a structure for absorbing an electromagnetic wave according to the present invention, and FIG. 3 is a perspective view illustrating a detailed structure for absorbing an electromagnetic wave in a bonding wire and a conductive lead connected thereto.

Referring to FIG. 2, electromagnetic wave absorbing films 10 and 12 are uniformly coated on both or either of a conductive lead 2 and a bonding wire 8. The electromagnetic wave absorbing films 10 and 12 form a closed loop.

The electromagnetic wave absorbing films 10 and 12 are formed by coating an electromagnetic wave absorbent on predetermined portions of the conductive lead 2 and/or the bonding wire to a predetermined constant thickness and drying the coated electromagnetic wave absorbent. Here, the electromagnetic wave absorbent is made by mixing an electromagnetic wave absorbent powder with a liquid polymer resin.

If necessary, both ends of the conductive lead 2 or the bonding wire 8 may not be coated with the electromagnetic wave absorbent, considering a joint strength or a contact resistance.

That is, an entire surface of the conductive lead 2 may be coated, except a portion where the bonding wire 8 is bonded or a portion where the bonding wire is soldered to the PCB. Also, an entire surface of the bonding wire 8 may be uniformly coated, except a portion where the bonding wire 8 is bonded with the semiconductor chip 1 or a portion where the bonding wire 8 is bonded with the conductive lead.

A method for manufacturing the above-described structure will now be described in brief. In the case of the conductive lead 2, a flat metal plate is pressed and plated. A portion where the coating of the electromagnetic wave absorbent is unnecessary is masked using a masking tape and so on. Then, the remaining portion is coated and dried using a dipping method, thereby forming the electromagnetic wave absorbent film. Then, a semiconductor packaging process is performed. In the case of the bonding wire, only a necessary portion can be coated through the above processes.

The electromagnetic wave absorbent powder may be any one selected from the group consisting of carbon graphite, Ni—Zn based ferrite, Mn—Zn based ferrite, Cu—Zn based ferrite, Mg—Zn based ferrite and barium based ferrite, which are soft magnetic materials with a spinel crystal structure. Preferably, size of particle may be below 50 μm. The ferrites are plasticized.

The liquid polymer resin must have close adherence to the conductive lead and the bonding wire. Also, it is preferable that the liquid polymer resin is flexible and the liquid polymer resin must not change in its characteristic and must not influence other components when reflowing the semiconductor package with a solder cream in a surface mount process (at about 270□ within 10 minutes). An epoxy-based, polyimide-based or polyamide-based material may be used as the polymer resin.

When a magnetic filed is applied from an outside, a magnetic loss and a reflection of an electromagnetic wave are caused due to a spinel of a ferrite magnetic atom and an electrical conductivity, such that the ferrite magnetic material absorbs or shields an external electromagnetic wave. Due to such a phenomenon, an amount of the electromagnetic wave applied from the outside is reduced and an amount of the electromagnetic wave emitted to the outside is reduced. Also, a spurious signal such as a noise flowing inside the semiconductor chip can be reduced due to the spinel of the soft magnetic material.

Referring to FIG. 3, the electromagnetic wave absorbing films 10 and 12 are formed by coating the electromagnetic wave absorbent on the conductive lead 2 and the bonding wire 8. The electromagnetic wave absorbing film is not coated on a portion where the conductive lead and the bonding wire are connected together.

Accordingly, the ferrite materials of the electromagnetic wave absorbing films can surely attenuate the electromagnetic interference occurring between the adjacent conductive leads or bonding wires while the electrical signal is flowing through the conductive lead 2 and the bonding wire 8.

Also, the spurious signal flowing through the conductive lead and the bonding wire can be reduced due to the spinel of the soft magnetic material.

A strength of the magnetic field generated at the bonding wire or the conductive lead is decreased in proportion to a uniformly coated thickness, a coated length and a magnetic permeability of the magnetic substance forming a closed loop at an outside of the bonding wire or the conductive lead.

Likewise, the spurious signal flowing inside the bonding wire or the conductive lead is decreased depending on a uniformly coated thickness, a coated length and a frequency of the magnetic substance forming a closed loop at an outside of the bonding wire or the conductive lead. In order to reduce the spurious signal of a specific frequency, a magnetic substance which causes much attenuation at the specific frequency is selected. For example, Ni—Zn based ferrite is used at higher frequency rather than Mn—Zn based ferrite.

As described above, the semiconductor according to the present invention has following effects. The electromagnetic wave absorbing films forming a closed loop are uniformly coated on both or either of the bonding wire connected to the semiconductor chip and the conductive lead connected to the bonding wire. In this manner, the electromagnetic interference between the conductive lead and the bonding wire can be surely attenuated.

Also, the lead frame and the conductive lead can be shield from the electromagnetic wave applied from the outside of the semiconductor package.

In addition, the spurious signal flowing through the conductive lead and the bonding wire can be reduced.

Further, the above-described structure secures a sufficient heat resistance so that it can be tolerated even during the reflow process. The semiconductor packaging process is convenient due to the flexibility of the liquid polymer resin.

While the present invention has been described in detail, it should be understood that various changes, substitutions and alterations can be made hereto without departing from the spirit and scope of the invention as defined by the appended claims.

1. A semiconductor package electrically connecting a semiconductor chip to a conductive lead of a lead frame through a bonding wire, the semiconductor package being encapsulated by an insulating molding body, wherein an electromagnetic wave absorbing film is formed by coating an electromagnetic wave absorbent on predetermined portions or either of the bonding wire and the conductive lead to a predetermined constant thickness, the electromagnetic wave absorbing film forming a closed loop.

2. The semiconductor package of claim 1, wherein the electromagnetic wave absorbing film is formed except both end portions of the bonding wire and the conductive lead.

3. The semiconductor package of claim 1, wherein the electromagnetic wave absorbent is made by evenly mixing an electromagnetic wave absorbent powder with a liquid polymer resin.

4. The semiconductor package of claim 2, wherein the electromagnetic wave absorbent is made by evenly mixing an electromagnetic wave absorbent powder with a liquid polymer resin.

5. The semiconductor package of claim 3, wherein the electromagnetic wave absorbent powder is any one selected from the group consisting of carbon graphite, Ni—Zn based ferrite, Mn—Zn based ferrite, Cu—Zn based ferrite, Mg—Zn based ferrite and barium based ferrite, size of the particle being below 50 μm, the ferrites being plasticized.

6. The semiconductor package of claim 4, wherein the electromagnetic wave absorbent powder is any one selected from the group consisting of carbon graphite, Ni—Zn based ferrite, Mn—Zn based ferrite, Cu—Zn based ferrite, Mg—Zn based ferrite and barium based ferrite, size of the particle being below 50 μm, the ferrites being plasticized.
